(19) United States
(12) Patent Application Publication
(10) Pub. No.: US 2024/0155905 A1
(43) Pub. Date: May 9, 2024

(54) DISPLAY PANEL AND DISPLAY APPARATUS

(71) Applicant: .BOE TECHNOLOGY GROUP CO., LTD., Beijing (CN)

(72) Inventors: Jianchao ZHU, Beijing (CN); Shiming SHI, Beijing (CN); Libin LIU, Beijing (CN)

(21) Appl. No.: 18/279,305

(22) PCT Filed: Oct. 22, 2021
(86) PCT No.: PCT/CN2021/125708

§ 371 Date: Aug. 29, 2023

(30) Foreign Application Priority Data
Mar. 29, 2021 (CN) 202110334647.8

(51) Int. Cl. H10K 59/35; H10K 59/126; H10K 59/131; H10K 59/80; H10K 59/88; H10K 102/00

(52) U.S. Cl. CPC H10K 59/353; H10K 59/126; H10K 59/131; H10K 59/80518; H10K 59/80524; H10K 59/88; H10K 2102/3031

(57) ABSTRACT

The present invention provides a display panel and a display apparatus, for use in achieving double-sided display. The display panel provided by embodiments of the present invention comprises: a transparent substrate comprising a display region, the display region comprising a plurality of first light emitting regions arranged in an array mode along a first direction and a second direction, and a plurality of second light emitting regions arranged in an array mode along the first direction and the second direction, the first light emitting regions and the second light emitting regions being alternately arranged along a third direction, the first direction intersecting with the second direction, and the third direction intersecting with both the first direction and the second direction.

### CROSS REFERENCE TO RELATED APPLICATION

The present application is a National Stage of International Application No. PCT/CN2021/125708, filed on Oct. 22, 2021, which claims the priority to Chinese Patent Application No. 202110334647.8, filed to China National Intellectual Property Administration on Mar. 29, 2021, which is incorporated in its entirety herein by reference.

### TECHNICAL FIELD

The present disclosure relates to the technical field of display, and particularly relates to a display panel and a display apparatus.

### BACKGROUND

At present, with the advancement of information transmission and the evolution of electronic products, demands for breakthroughs in functions or display modes, in addition to the continuous development and improvement in the response speed, resolution and image quality, of organic light emitting display apparatuses have been put forward. Therefore, a trend towards double-sided display is a significant development direction of display apparatuses in the future. Double-sided display can extend a picture space and broaden the field of vision. Further, it can switch swiftly and handle more jobs. Thus, it has a great potential application value in advertising display, video conferencing and other fields. An existing double-sided display technology is actually a double-screen display technology. That is, double screens are used for double-sided display. The screens are thick, heavy, costly, and far from satisfying people's demand for double-sided-screen display.

### SUMMARY

Embodiments of the present disclosure provide a display panel and a display apparatus, so as to achieve double-sided display.

An embodiment of the present disclosure provides a display panel. The display panel includes: a transparent substrate, including a display region, where the display region includes a plurality of first light emitting regions arranged in an array in a first direction and a second direction, and a plurality of second light emitting regions arranged in an array in the first direction and the second direction, the first light emitting regions and the second light emitting regions are alternately arranged in a third direction, the first direction intersects with the second direction, and the third direction intersects with both the first direction and the second direction; light emitting devices on one side of the transparent substrate, including top-emitting light emitting devices in the first light emitting regions and bottom-emitting light emitting devices in the second light emitting regions; and driving circuits in the first light emitting regions and between a film layer in which the light emitting devices are located and the transparent substrate, electrically connected to the light emitting devices, where the driving circuits include a plurality of pixel circuits of which a quantity is equal to a quantity of the first light emitting regions, and a plurality of signal lines electrically connected to the pixel circuits.

In some embodiments, the top-emitting light emitting device includes: a first anode, including a reflective material; a first light emitting layer on one side of the first anode facing away from the driving circuit; and a first cathode on one side of the first light emitting layer facing away from the first anode, including a light transmitting material; the bottom-emitting light emitting device includes: a second anode, including a light transmitting material and located in the same film layer as the first anode; a second light emitting layer on one side of the second anode facing away from the driving circuit and in the same film layer as the first light emitting layer; a second cathode, including a light transmitting material, located on one side of the second light emitting layer facing away from the second anode, and arranged in the same layer as the first cathode to form an entire surface connected electrode; and a third cathode in the second light emitting region and on one side of the second cathode facing away from the second light emitting layer, including a reflective material.

In some embodiments, the display panel further includes: a light shielding layer between the transparent substrate and a film layer in which the driving circuits are located, where the plurality of the first light emitting regions are connected to one another, and the light shielding layer covers a zone formed by the plurality of first light emitting regions connected to one another; and the light shielding layer further has first apertures exposing the second light emitting regions, and a quantity of the first apertures is equal to a quantity of the second light emitting regions.

In some embodiments, a quantity of the top-emitting light emitting devices included in each of the first light emitting regions is equal to a quantity of the bottom-emitting light emitting devices included in each of the second light emitting regions.

In some embodiments, types of light colors of the top-emitting light emitting devices included in the first light emitting region are the same as types of light colors of the bottom-emitting light emitting devices included in the second light emitting region.

In some embodiments, each of the first light emitting regions includes: a red top-emitting light emitting device, a blue top-emitting light emitting device, and a green top-emitting light emitting device; each of the second light emitting regions includes: a red bottom-emitting light emitting device, a blue bottom-emitting light emitting device, and a green bottom-emitting light emitting device.

In some embodiments, the first light emitting regions arranged in an array are divided into a plurality of first light emitting columns extending in the first direction and arranged in the second direction; and the plurality of second light emitting regions arranged in an array are divided into a plurality of second light emitting columns extending in the first direction and arranged in the second direction; in odd-numbered columns of the first light emitting columns, types of light colors of the top-emitting light emitting devices included in each of the first light emitting regions are the same; in even-numbered columns of the first light emitting columns, types of light colors of the top-emitting light emitting devices included in each of the first light emitting regions are the same; and types of light colors of the top-emitting light emitting devices included in each of the first light emitting regions in the odd-numbered columns of the first light emitting columns are not exactly the same as types of light colors of the top-emitting light emitting devices included in each of the first light emitting regions in the even-numbered columns of the first light emitting columns; in odd-numbered columns of the second light emitting columns, types of light colors of the bottom-emitting light emitting devices included in each of the second light emitting regions are the same; in even-numbered columns of the second light emitting columns, types of light colors of the bottom-emitting light emitting devices included in each of the second light emitting regions are the same; and types of light colors of the bottom-emitting light emitting devices included in each of the second light emitting regions in the odd-numbered columns of the second light emitting columns are not exactly the same as types of light colors of the bottom-emitting light emitting devices included in each of the second light emitting regions in the even-numbered columns of the second light emitting columns; and the types of the light colors of the top-emitting light emitting devices included in each of the first light emitting regions in the odd-numbered columns of the first light emitting columns are the same as types of the light colors of the bottom-emitting light emitting devices included in each of the second light emitting regions in the odd-numbered columns of the second light emitting columns; the types of the light colors of the top-emitting light emitting devices included in each of the first light emitting regions in the even-numbered columns of the first light emitting columns are the same as types of the light colors of the bottom-emitting light emitting devices included in each of the second light emitting regions in the even-numbered columns of the second light emitting columns.

In some embodiments, each of the first light emitting regions in the odd-numbered columns of the first light emitting columns includes: a red top-emitting light emitting device and a green top-emitting light emitting device arranged in the second direction. Each of the first light emitting regions in the even-numbered columns of the first light emitting columns includes: a blue top-emitting light emitting device and the green top-emitting light emitting device arranged in the second direction; each of the second light emitting regions in the odd-numbered columns of the second light emitting columns includes: a red bottom-emitting light emitting device and a green bottom-emitting light emitting device arranged in the second direction; and each of the second light emitting regions in the even-numbered columns of the second light emitting columns includes: a blue bottom-emitting light emitting device and the green bottom-emitting light emitting device arranged in the second direction.

In some embodiments, a quantity of the top-emitting light emitting devices included in each of the first light emitting regions is different from a quantity of the bottom-emitting light emitting devices included in each of the second light emitting regions.

In some embodiments, each of the first light emitting regions includes three top-emitting light emitting devices having different light colors; and each of the second light emitting regions includes one bottom-emitting light emitting device.

In some embodiments, each of the first light emitting regions includes: a red top-emitting light emitting device, a blue top-emitting light emitting device, and a green top-emitting light emitting device; the plurality of second light emitting regions arranged in an array are divided into a plurality of second light emitting groups arranged in the second direction; each of the second light emitting groups includes: a second red light emitting column, a second blue light emitting column and a second green light emitting column extending in the first direction and sequentially arranged in the second direction; each of the second light emitting regions in the second red light emitting column includes: a red bottom-emitting light emitting device; each of the second light emitting regions in the second blue light emitting column includes: a blue bottom-emitting light emitting device; each of the second light emitting regions in the second green light emitting column includes: a green bottom-emitting light emitting device.

In some embodiments, each of the first light emitting regions includes: a red top-emitting light emitting device, a blue top-emitting light emitting device, and a green top-emitting light emitting device; the plurality of second light emitting regions arranged in an array are divided into a plurality of pixel groups, and each of the pixel groups includes four of the second light emitting regions in two rows and two columns; wherein each of the pixel groups at least includes a red bottom-emitting light emitting device, a blue bottom-emitting light emitting device, and a green top-emitting light emitting device.

In some embodiments, each of the first light emitting regions includes m of the top-emitting light emitting devices, and each of the second light emitting regions includes n of the bottom-emitting light emitting devices, where m and n are both positive integers; and one of the pixel circuits corresponding to the first light emitting region includes: m first pixel circuits, where each of the first pixel circuits is electrically connected to one of the top-emitting light emitting devices; and n second pixel circuits, where each of the second pixel circuits is electrically connected to one of the bottom-emitting light emitting devices.

In some embodiments, the plurality of signal lines include: a plurality of gate drive signal lines extending in the second direction; wherein the first pixel circuit and the second pixel circuit in the same pixel circuit are arranged in the second direction, and the first pixel circuit and the second pixel circuit in the same pixel circuit share the gate drive signal line.

In some embodiments, the plurality of first light emitting regions arranged in an array are divided into a plurality of first light emitting rows extending in the second direction and arranged in the first direction; one of the pixel circuits corresponding to the first light emitting region includes: three first pixel circuits, where each of the first pixel circuits is electrically connected to one of the top-emitting light emitting devices. One of the pixel circuits corresponding to each of the first light emitting regions in odd-numbered rows of the first light emitting rows further includes: two dummy pixel circuits. One of the pixel circuits corresponding to each of the first light emitting regions in even-numbered rows of the first light emitting rows further includes: two second pixel circuits electrically connected to two of the bottom-emitting light emitting devices adjacent in the second direction, respectively, where the dummy pixel circuits have the same circuit composition as the second pixel circuits.

In some embodiments, the plurality of signal lines include: a plurality of gate drive signal lines extending in the second direction; wherein in one of the pixel circuits corresponding to each of the first light emitting regions in the odd-numbered rows of the first light emitting rows, the first pixel circuit and the dummy pixel circuit are arranged in the second direction. In one of the pixel circuits corresponding to each of the first light emitting regions in the even-numbered rows of the first light emitting rows, the first pixel circuit and the second pixel circuit are arranged in the second direction, and the first pixel circuit and the second pixel circuit share the gate drive signal line.

In some embodiments, the first pixel circuit has the same circuit composition as the second pixel circuit.

In some embodiments, each of the first light emitting regions includes m of the top-emitting light emitting devices, and each of the second light emitting regions includes m of the bottom-emitting light emitting devices, where m is a positive integer. Each of the pixel circuits includes: m third pixel circuits; and m fourth pixel circuits, where each of the fourth pixel circuits includes: a first sub-pixel circuit and a second sub-pixel circuit electrically connected to the third pixel circuit; the first sub-pixel circuit is further electrically connected to the top-emitting light emitting device, and the second sub-pixel circuit is further electrically connected to the bottom-emitting light emitting device; and the light emitting devices electrically connected to the first sub-pixel circuit and the second sub-pixel circuit electrically connected to the same third pixel circuit have the same light color.

In some embodiments, the third pixel circuit includes: a driver transistor. The signal line includes: a first light emitting control signal line and a second light emitting control signal line. The first sub-pixel circuit includes: a first transistor, where a source electrode of the first transistor is electrically connected to a drain electrode of the driver transistor, a gate electrode of the first transistor is electrically connected to the first light emitting control signal line, and a drain electrode of the first transistor is electrically connected to the top-emitting light emitting device. The second sub-pixel circuit includes: a second transistor, where a source electrode of the second transistor is electrically connected to a drain electrode of the driver transistor, a gate electrode of the second transistor is electrically connected to the second light emitting control signal line, and a drain electrode of the second transistor is electrically connected to the bottom-emitting light emitting device.

An embodiment of the present disclosure provides a display apparatus. The display apparatus includes the display panel provided by the embodiments of the present disclosure.

### BRIEF DESCRIPTION OF FIGURES

To describe technical solutions in embodiments of the present disclosure more clearly, the accompanying drawings required for describing the embodiments are briefly introduced below. Obviously, the accompanying drawings in the following description show merely some embodiments of the present disclosure, and those of ordinary skill in the art would also be able to derive other accompanying drawings from these accompanying drawings without creative efforts.

FIG. 1 is a schematic structural diagram of a display panel provided by an embodiment of the present disclosure.

FIG. 2 is a schematic structural diagram of another display panel provided by an embodiment of the present disclosure.

FIG. 3 is a schematic structural diagram of yet another display panel provided by an embodiment of the present disclosure.

FIG. 4 is a schematic structural diagram of yet another display panel provided by an embodiment of the present disclosure.

FIG. 5 is a schematic structural diagram of yet another display panel provided by an embodiment of the present disclosure.

FIG. 6 is a schematic structural diagram of yet another display panel provided by an embodiment of the present disclosure.

FIG. 7 is a schematic structural diagram of yet another display panel provided by an embodiment of the present disclosure.

FIG. 8 is a schematic structural diagram of yet another display panel provided by an embodiment of the present disclosure.

FIG. 9 is a schematic structural diagram of yet another display panel provided by an embodiment of the present disclosure.

FIG. 10 is a schematic structural diagram of still another display panel provided by an embodiment of the present disclosure.

### DETAILED DESCRIPTION

For making objectives, technical solutions and advantages of embodiments of the present disclosure clearer, the technical solutions of the embodiments of the present disclosure will be clearly and completely described below in conjunction with the accompanying drawings in the embodiments of the present disclosure. Apparently, the embodiments described are some embodiments rather than all embodiments of the present disclosure. The embodiments in the present disclosure and features of the embodiments can be combined with each other without conflict. Based on the embodiments of the present disclosure, all other embodiments obtained by those of ordinary skill in the art without making creative efforts fall within the scope of protection of the present disclosure.

Unless otherwise defined, technical or scientific terms used in the present disclosure should have ordinary meanings as understood by those of ordinary skill in the art to which the present disclosure belongs. “First”, “second”, and other similar words used in the present disclosure do not indicate any order, amount or importance, but are only used to distinguish different components. “Include”, “comprise”, and other similar words indicate that elements or objects before the word include elements or objects after the word and their equivalents, without excluding other elements or objects. “Connection”, “connected”, and other similar words are not limited to physical or mechanical connections, but can include electrical connections, which can be direct or indirect.

It should be noted that a size and a shape of each figure in the drawings do not reflect a true scale, but only for illustrating the present disclosure. Throughout the drawings, identical or similar reference numerals denote identical or similar elements or elements having identical or similar functions.

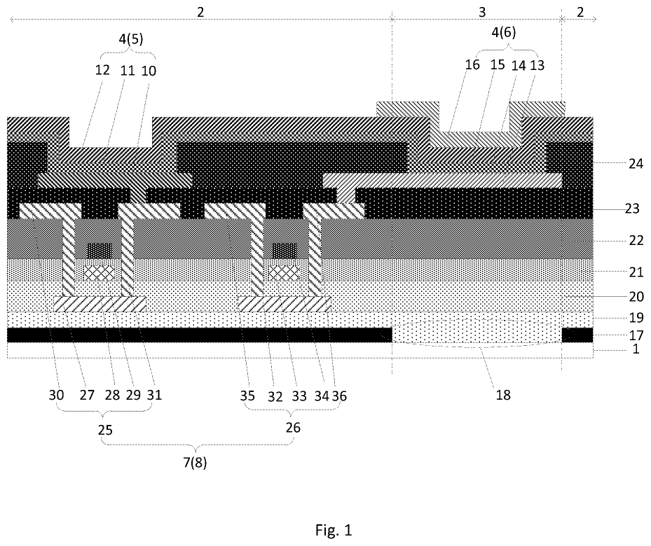

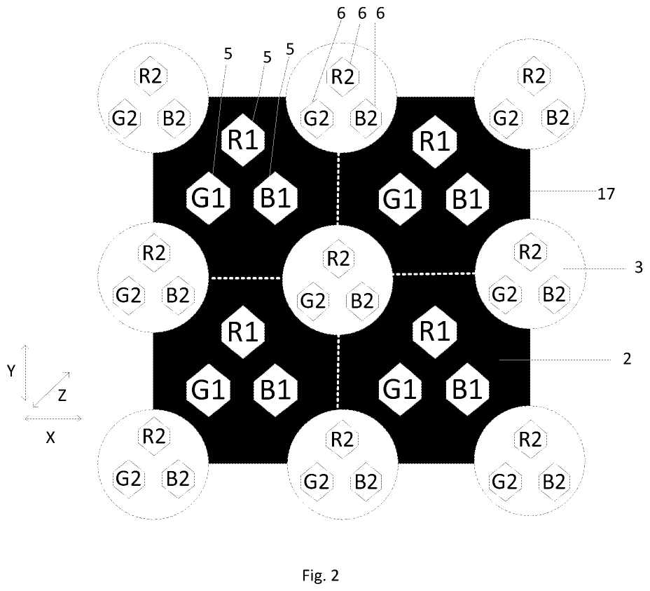

An embodiment of the present disclosure provides a display panel. As shown in FIGS. 1 and 2, the display panel includes: a transparent substrate 1 including a display region, where the display region includes a plurality of first light emitting regions 2 arranged in an array in a first direction Y and a second direction X, and a plurality of second light emitting regions 3 arranged in an array in the first direction Y and the second direction X, the first light emitting regions 2 and the second light emitting regions 3 are alternately arranged in a third direction Z, the first direction Y intersects with the second direction X, and the third direction Z intersects with both the first direction Y and the second direction X; light emitting devices 4 located on one side of the transparent substrate 1 and including top-emitting light emitting devices 5 located in the first light emitting regions 2 and bottom-emitting light emitting devices 6 located in the second light emitting regions 3; and driving circuits 7 located in the first light emitting regions 2 and between a film layer in which the light emitting devices 4 are located and the transparent substrate 1, and electrically connected to the light emitting devices 4, where the driving circuits include a plurality of corresponding pixel circuits 8 of which the quantity is equal to that of the first light emitting regions 2 and a plurality of signal lines 9 electrically connected to the pixel circuits 8.

In the display panel provided by the embodiment of the present disclosure, the top-emitting light emitting devices emitting light from a front surface and the bottom-emitting light emitting devices emitting light from a back surface are simultaneously formed on a transparent substrate, such that the display panel can emit light and display a picture on the front surface and the back surface simultaneously, that is, can achieve double-sided-screen display. Compared with a conventional solution of achieving double-sided-screen display by attaching two screens to each other, the solution of the present disclosure achieves double-sided-screen display by using only one display panel. In this way, the double-sided display panel provided by the embodiment of the present disclosure well achieves a thin and light design, and can reduce cost of a display screen. Moreover, the driving circuits are only arranged in the first light emitting regions. That is, orthographic projections of the driving circuits on the transparent substrate do not overlap with the second light emitting regions. In this way, a light emitting area of the second light emitting regions can be increased, light emitting efficiency of bottom emission can be improved, and further a display effect of back display of bottom emission can be improved.

It should be noted that the embodiment of the present disclosure regards one side of the transparent substrate facing the light emitting device as the front surface of the display panel, and one side of the transparent substrate facing away from the light emitting device as the back surface of the display panel.

It should be noted that FIG. 2 only shows a partial zone of the display panel. Only partial first light emitting regions are shown around partial second light emitting regions.

In some embodiments, as shown in FIG. 1, the top-emitting light emitting device 5 includes: a first anode 10 including a reflective material; a first light emitting layer 11 located on one side of the first anode 10 facing away from the driving circuit 7; and a first cathode 12 located on one side of the first light emitting layer 11 facing away from the first anode 10 and including a light transmitting material. The bottom-emitting light emitting device 6 includes: a second anode 13 including a light transmitting material and located in the same film layer as the first anode 10; a second light emitting layer 14 located on one side of the second anode 13 facing away from the driving circuit 7 and located in the same film layer as the first light emitting layer 11; a second cathode 15 including a light transmitting material, located on one side of the second light emitting layer facing away from the second anode, and arranged in the same layer as the first cathode to form an entire surface connected electrode; and a third cathode 16 located in the second light emitting region and on one side of the second cathode facing away from the second light emitting layer and including a reflective material.

In the display panel provided by the embodiment of the present disclosure, in the top-emitting light emitting device, the first anode includes the reflective material, and the first cathode includes the light transmitting material. In this way, the light emitting device can emit light towards a front surface of the display panel in the first light emitting region.

It should be noted that in the display panel provided by the embodiment of the present disclosure, the light emitting device is an electroluminescent device. During specific implementation, the electroluminescent device may be an organic light emitting diode device or a quantum dot light emitting diode device.

It should be noted that in some embodiments, as shown in FIG. 1, the first cathode 12 and the second anode 13 are integrated. After a light emitting layer is formed, a cathode covering an entire surface may be formed. The cathode in the first light emitting region serves as the first cathode for top emission, and the cathode in the second light emitting region serves as the second cathode for bottom emission. In some embodiments, as shown in FIG. 1, when the top-emitting light emitting device 5 and the bottom-emitting light emitting device 6 have the same light color, the first light emitting layer 11 and the second light emitting layer 14 having the same light color may be formed in the same process flow, that is, the first light emitting layer 11 and the second light emitting layer 14 having the same light color may be integrally connected.

During specific implementation, the first light emitting layer and the second light emitting layer include, for example, at least one of film layers such as an electron injection layer, an electron transport layer, an organic light emitting layer, a hole transport layer, or an electron blocking layer.

In some embodiments, a material of the first anode includes: an indium tin oxide (ITO)/silver (Ag)/ITO laminate.

In some embodiments, a material of the second anode includes: ITO.

In some embodiments, a material of the first cathode and the second cathode includes: magnesium or silver.

In some embodiments, a material of the third cathode includes: aluminum.

In some embodiments, as shown in FIGS. 1 and 2, the display panel further includes: a light shielding layer 17 located between the transparent substrate 1 and a film layer in which the driving circuits 7 are located, where the plurality of the first light emitting regions 2 are connected to one another so as to form a continuous zone, and the light shielding layer 17 covers a zone formed by the plurality of first light emitting regions 2 connected to one another; and the light shielding layer 17 further has first apertures 18 exposing the second light emitting regions 3, and the quantity of the first apertures 18 is equal to the quantity of the second light emitting regions 3.

In the display panel provided by the embodiment of the present disclosure, the light shielding layer is arranged such that two sides can be prevented from influencing each other when displaying different pictures simultaneously, and an effect of shielding the driving circuit from light can be achieved to prolong the service life of the driving circuit.

In some embodiments, as shown in FIGS. 1 and 2, an orthographic projection of the first aperture 18 on the transparent substrate 1 coincides with the second light emitting region 3.

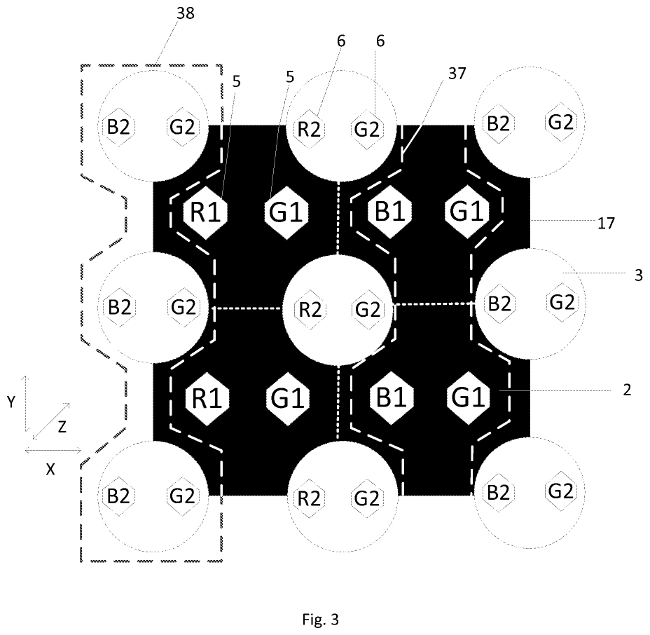

In some embodiments, as shown in FIGS. 2 and 3, the quantity of the top-emitting light emitting devices 5 included in each of the first light emitting regions 2 is equal to the quantity of the bottom-emitting light emitting devices 6 included in each of the second light emitting regions 3.

In the display panel provided by the embodiment of the present disclosure, the quantity of top-emitting light emitting devices included in the first light emitting region is equal to the quantity of the bottom-emitting light emitting devices included in the second light emitting region, such that resolution of front display of the display panel is the same as resolution of back display of the display panel.

In some embodiments, as shown in FIGS. 2 and 3, types of light colors of the top-emitting light emitting devices 5 included in the first light emitting region 2 are the same as types of light colors of the bottom-emitting light emitting devices 6 included in the second light emitting region 3.

In the display panel provided by the embodiment of the present disclosure, when the quantity of the top-emitting light emitting devices included in the first light emitting region is equal to that of the bottom-emitting light emitting devices included in the second light emitting region, the types of the light colors of the top-emitting light emitting devices included in the first light emitting region are the same as the types of the light colors of the bottom-emitting light emitting devices included in the second light emitting region. That is, the pixel circuit in the first light emitting region may drive the top-emitting light emitting device and the bottom-emitting light emitting device having the same light color, such that design difficulty of the driving circuit can be lowered.

In some embodiments, as shown in FIG. 2, each of the first light emitting regions 2 includes: a red top-emitting light emitting device R1, a blue top-emitting light emitting device B1, and a green top-emitting light emitting device G1.

Each of the second light emitting regions 3 includes: a red bottom-emitting light emitting device R2, a blue bottom-emitting light emitting device B2, and a green bottom-emitting light emitting device G2.

In some embodiments, as shown in FIG. 3, the plurality of first light emitting regions 2 arranged in an array are divided into a plurality of first light emitting columns 37 extending in the first direction Y and arranged in the second direction X; and the plurality of second light emitting regions 3 arranged in an array are divided into a plurality of second light emitting columns 38 extending in the first direction Y and arranged in the second direction X.

In odd-numbered columns of the first light emitting columns 37, types of light colors of the top-emitting light emitting devices 5 included in each of the first light emitting regions 2 are the same. In even-numbered columns of the first light emitting columns 37, types of light colors of the top-emitting light emitting devices 5 included in each of the first light emitting regions 2 are the same. Types of light colors of the top-emitting light emitting devices 5 included in each of the first light emitting regions 2 in the odd-numbered columns of the first light emitting columns 37 are not exactly the same as types of light colors of the top-emitting light emitting devices 5 included in each of the first light emitting regions 2 in the even-numbered columns of the first light emitting columns 37.

In odd-numbered columns of the second light emitting columns 38, types of light colors of the bottom-emitting light emitting devices 6 included in each of the second light emitting regions 3 are the same. In even-numbered columns of the second light emitting columns 38, types of light colors of the bottom-emitting light emitting devices 6 included in each of the second light emitting regions 3 are the same. Types of light colors of the bottom-emitting light emitting devices 6 included in each of the second light emitting regions 3 in the odd-numbered columns of the second light emitting columns 38 are not exactly the same as types of light colors of the bottom-emitting light emitting devices 6 included in each of the second light emitting regions 3 in the even-numbered columns of the second light emitting columns 38.

The types of the light colors of the top-emitting light emitting devices 5 included in each of the first light emitting regions 2 in the odd-numbered columns of the first light emitting columns 37 are the same as types of the light colors of the bottom-emitting light emitting devices 6 included in each of the second light emitting regions 3 in the odd-numbered columns of the second light emitting columns 38. The types of the light colors of the top-emitting light emitting devices 5 included in each of the first light emitting regions 2 in the even-numbered columns of the first light emitting columns 37 are the same as types of the light colors of the bottom-emitting light emitting devices 6 included in each of the second light emitting regions 3 in the even-numbered columns of the second light emitting columns 38.

In this way, through a sub-pixel rendering algorithm, a plurality of light emitting devices included in one light emitting region of the odd-numbered column and light emitting devices, having different light colors from the odd-numbered column, in one light emitting region of an even-numbered column adjacent to the odd-numbered column may constitute one pixel, such that resolution of the display panel can be improved.

In some embodiments, as shown in FIG. 3, each of the first light emitting regions 2 in the odd-numbered columns of the first light emitting columns 37 includes: a red top-emitting light emitting device R1 and a green top-emitting light emitting device G1 arranged in the second direction X; and each of the first light emitting regions 2 in the even-numbered columns of the first light emitting columns 37 includes: a blue top-emitting light emitting device B1 and a green top-emitting light emitting device G1 arranged in the second direction.

Each of the second light emitting regions 3 in the odd-numbered columns of the second light emitting columns 38 includes: a red bottom-emitting light emitting device R2 and a green bottom-emitting light emitting device G2 arranged in the second direction X. Each of the second light emitting regions 3 in the even-numbered columns of the second light emitting columns 38 includes: a blue bottom-emitting light emitting device B2 and the green bottom-emitting light emitting device G2 arranged in the second direction X.

It should be noted that FIG. 3 only shows some of the first light emitting regions and some of the second light emitting regions of the display panel. The first second light emitting column 38 on the left in FIG. 3 is an even-numbered column, and the first first light emitting column 37 on the left in FIG. 3 is an odd-numbered column.

In the display panel as shown in FIG. 3 provided by the embodiment of the present disclosure, the red top-emitting light emitting device R1 and the green top-emitting light emitting device G1 may constitute one pixel unit for front display by using the adjacent blue top-emitting light emitting device B1. The red bottom-emitting light emitting device R2 and the green bottom-emitting light emitting device G2 may constitute oen pixel unit for back display by using the adjacent blue bottom-emitting light emitting device B2.

In some embodiments, as shown in FIG. 3, the blue top-emitting light emitting device B1 in the even-numbered column of the first light emitting column 37 is adjacent to the green top-emitting light emitting device G1 in the odd-numbered column of the first light emitting column 37 adjacent to the even-numbered column of the first light emitting column 37. The blue bottom-emitting light emitting device B2 in the even-numbered column of the second light emitting column 38 is adjacent to the green bottom-emitting light emitting device G2 in the odd-numbered column of the second light emitting column 38 adjacent to the even-numbered column of the second light emitting column 38.

During specific implementation, when light colors of the light emitting devices included in the light emitting regions of the odd-numbered column are not exactly the same as light colors of the light emitting devices included in the light emitting regions of the even-numbered column, the types of the light colors included in each column may be selected according to actual needs. During specific implementation, when each of the first light emitting regions and the second light emitting regions includes two light emitting devices, the odd-numbered column may include red light emitting devices and blue light emitting devices, and the even-numbered column may include green light emitting devices and blue light emitting devices. Certainly, during specific implementation, for the same light emitting region, the types of the light colors of the light emitting devices in the odd-numbered column may be interchanged with the types of the light colors of the light emitting devices in the even-numbered column.

In some embodiments, as shown in FIGS. 2 and 3, a light emitting area of the top-emitting light emitting device is greater than a light emitting area of the bottom-emitting light emitting device.

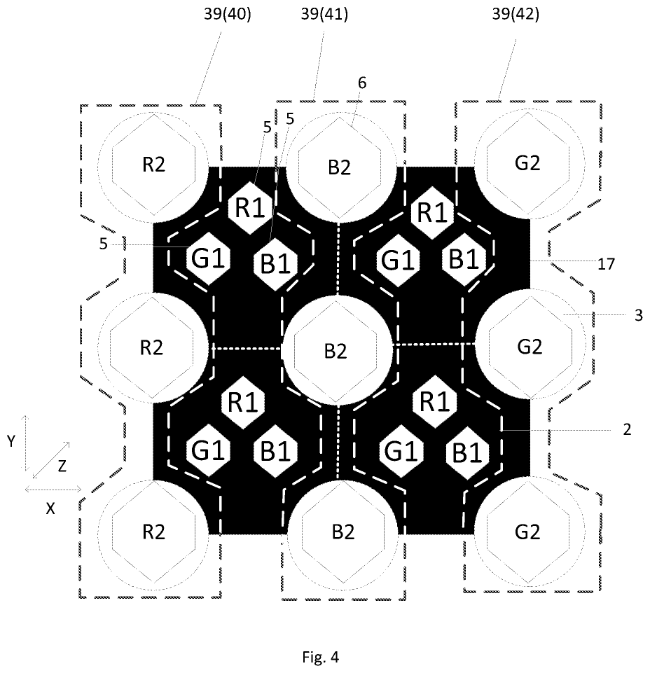

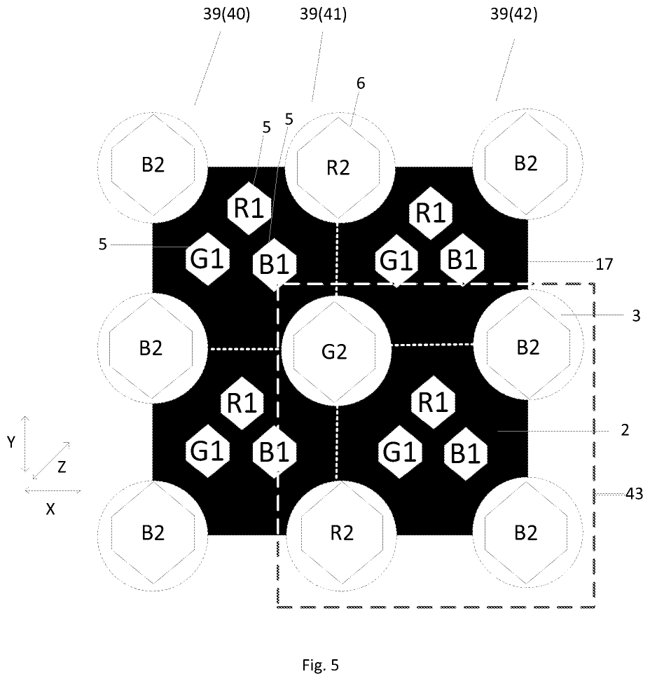

In some embodiments, as shown in FIGS. 4 and 5, the quantity of the top-emitting light emitting devices 5 included in each of the first light emitting regions 2 is different from that of the bottom-emitting light emitting devices 6 included in each of the second light emitting regions 3.

That is, in the display panel provided by the embodiment of the present disclosure, the resolution of front display may be set to be different from the resolution of back display.

During specific implementation, the corresponding resolution may be selected according to an actual application scenario of front display and back display.

In some embodiments, as shown in FIGS. 4 and 5, the quantity of the top-emitting light emitting devices 5 included in each of the first light emitting regions 2 is greater than that of the bottom-emitting light emitting devices 6 included in each of the second light emitting regions 3.

In some embodiments, as shown in FIGS. 4 and 5, an area of a light emitting region of each of the top-emitting light emitting devices 5 is smaller than an area of a light emitting region of each of the bottom-emitting light emitting devices 6.

In some embodiments, as shown in FIGS. 4 and 5, each of the first light emitting regions 2 includes three top-emitting light emitting devices 5 having different light colors.

Each of the second light emitting regions 3 includes one bottom-emitting light emitting device 6.

In some embodiments, as shown in FIG. 4, each of the first light emitting regions 2 includes: a red top-emitting light emitting device R1, a blue top-emitting light emitting device B1, and a green top-emitting light emitting device G1.

The plurality of second light emitting regions 3 arranged in an array are divided into a plurality of second light emitting groups 39 arranged in the second direction X.

Each of the second light emitting groups 39 includes: a second red light emitting column 40, a second blue light emitting column 41 and a second green light emitting column 42 extending in the first direction Y and sequentially arranged in the second direction X.

Each of the second light emitting regions 3 in the second red light emitting column 40 includes: a red bottom-emitting light emitting device R1.

Each of the second light emitting regions 3 in the second blue light emitting column 41 includes: a blue bottom-emitting light emitting device B1.

Each of the second light emitting regions 3 in the second green light emitting column 42 includes: a green bottom-emitting light emitting device G1.

In the display panel as shown in FIG. 4 provided by the embodiment of the present disclosure, the light emitting devices included in each column of the second light emitting regions have the same light color, such that design difficulty of the driving circuit can be lowered.

In the display panel as shown in FIG. 4 provided by the embodiment of the present disclosure, a ratio of the resolution of front display to the resolution of back display is 3:1.

In some embodiments, as shown in FIG. 5, each of the first light emitting regions 1 includes: a red top-emitting light emitting device R1, a blue top-emitting light emitting device B1, and a green top-emitting light emitting device G1.

The plurality of second light emitting regions 3 arranged in an array are divided into a plurality of pixel groups 43, and each of the pixel groups 43 includes four of the second light emitting regions 3 in two rows and two columns.

Each of the pixel groups 43 at least includes a red bottom-emitting light emitting device R2, a blue bottom-emitting light emitting device B2, and a green top-emitting light emitting device G2.

That is, one pixel group serves as one pixel unit for back display.

In some embodiments, as shown in FIG. 5, in each of the pixel groups 43, two light emitting devices in a first column are a red bottom-emitting light emitting device R2 and a green top-emitting light emitting device G2, and light emitting devices in a second column are both blue bottom-emitting light emitting devices B2.

In the display panel provided by the embodiment of the present disclosure, the quantity of the blue bottom-emitting light emitting devices in each of the pixel groups is greater than that of the other two types of light emitting devices. In this way, blue light emitting efficiency can be improved, and uneven display caused by mismatch between brightness decay of the blue bottom-emitting light emitting devices and brightness decay of the other two types of light emitting devices can be avoided.

In the display panel as shown in FIG. 5 provided by the embodiment of the present disclosure, a ratio of the resolution of front display to the resolution of back display is 2:1.

Certainly, during specific implementation, a blue bottom-emitting light emitting device B2 in a pixel group 43 in FIG. 5 may be replaced with a red bottom-emitting light emitting device R2 or a green top-emitting light emitting device G2.

During specific implementation, the quantity and positions of red bottom-emitting light emitting devices R2, the quantity and positions of green top-emitting light emitting devices G2 and the quantity and positions of blue bottom-emitting light emitting devices B2 in each of the pixel groups may be selected according to actual needs.

In some embodiments, the top-emitting light emitting devices and the bottom-emitting light emitting devices may be driven by different circuits separately.

In some embodiments, each of the first light emitting regions includes m of the top-emitting light emitting devices, and each of the second light emitting regions includes n of the bottom-emitting light emitting devices, where m and n are both positive integers.

As shown in FIGS. 1, 6, 7 and 8, one of the pixel circuits 8 corresponding to the first light emitting region includes: m first pixel circuits 25, where each of the first pixel circuits 25 is electrically connected to one of the top-emitting light emitting devices 5; and n second pixel circuits 26, where each of the second pixel circuits 26 is electrically connected to one of the bottom-emitting light emitting devices 6.

In some embodiments, the plurality of signal lines 44 include: a plurality of gate drive signal lines 45 extending in the second direction X.

The first pixel circuit 25 and the second pixel circuit 26 in the same pixel circuit 8 are arranged in the second direction X, and the first pixel circuit 25 and the second pixel circuit 26 in the same pixel circuit 8 share the gate drive signal line 45.

In the display panel provided by the embodiment of the present disclosure, the first pixel circuit and the second pixel circuit located in the same pixel circuit share the gate drive signal line. In this way, the quantity of signal lines in the driving circuit can be reduced, and a wiring space can be saved, and therefore, a light emitting area of the second light emitting region can be increased, light emitting efficiency of back display of the display panel can be improved, and a back display effect of the display panel can be improved.

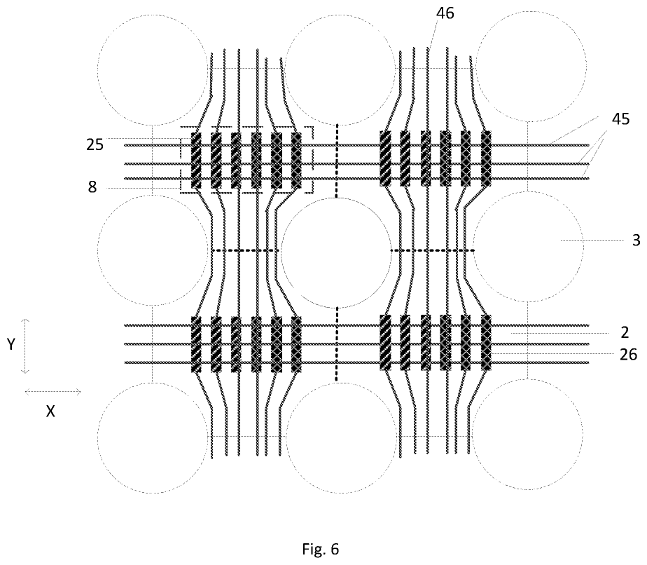

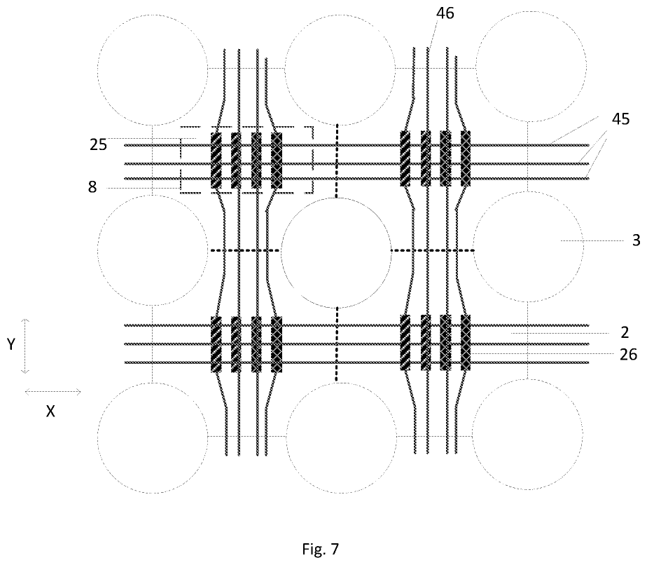

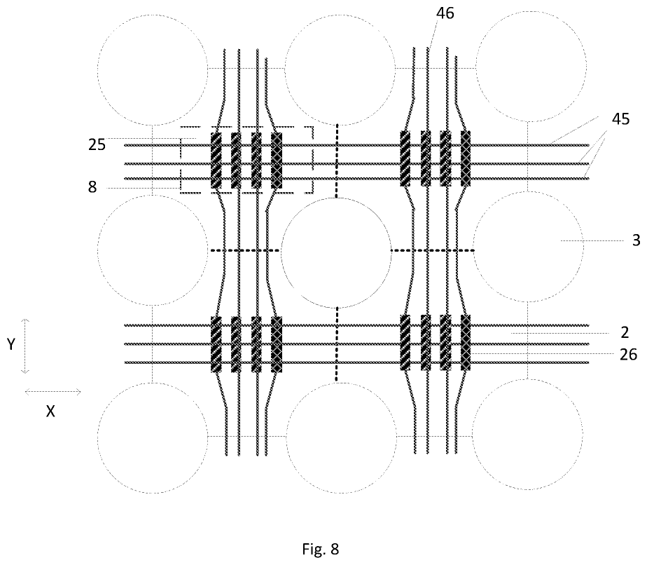

It should be noted that FIG. 6 shows a pixel circuit corresponding to the display panel as shown in FIG. 2, FIG. 7 shows a pixel circuit corresponding to the display panel as shown in FIG. 3, and FIG. 8 shows a pixel circuit corresponding to the display panel as shown in FIG. 4, for example.

As shown in FIG. 6, the pixel circuit 8 corresponding to each of the first light emitting regions 2 includes three first pixel circuits 25 and three second pixel circuits 26. The three first pixel circuits 25 and the three second pixel circuits 26 are arranged in the first direction X. The three first pixel circuits 25 drive a red top-emitting light emitting device, a blue top-emitting light emitting device and a green top-emitting light emitting device in one first light emitting region 2 to emit light, respectively. The three second pixel circuits 26 drive a red bottom-emitting light emitting device, a blue bottom-emitting light emitting device and a green bottom-emitting light emitting device in one second light emitting region 3 adjacent to the first light emitting region 2 to emit light, respectively.

As shown in FIG. 7, the pixel circuit 8 corresponding to each of the first light emitting regions 2 includes two first pixel circuits 25 and two second pixel circuits 26. The two first pixel circuits 25 and the two second pixel circuits 26 are arranged in the first direction X. During specific implementation, in each of the pixel circuits of the even-numbered columns, two first pixel circuits 25 drive a red top-emitting light emitting device and a green top-emitting light emitting device in one first light emitting region 2 to emit light, respectively; and two second pixel circuits 26 drive a red bottom-emitting light emitting device and a green bottom-emitting light emitting device in one second light emitting region 3 adjacent to the first light emitting region 2 to emit light, respectively. In each of the pixel circuits of the odd-numbered columns, two first pixel circuits 25 drive a blue top-emitting light emitting device and a green top-emitting light emitting device in one first light emitting region 2 to emit light, respectively; and two second pixel circuits 26 drive a blue top-emitting light emitting device and a green top-emitting light emitting device in a second light emitting region 3 adjacent to the first light emitting region 2 to emit light, respectively.

As shown in FIG. 8, the pixel circuit 8 corresponding to each of the first light emitting regions 2 includes three first pixel circuits 25 and one second pixel circuit 26. The three first pixel circuits 25 and one second pixel circuits 26 are arranged in the first direction X. The three first pixel circuits 25 drive a red top-emitting light emitting device, a blue top-emitting light emitting device and a green top-emitting light emitting device in a first light emitting region 2 to emit light, respectively. The one second pixel circuit 26 drives a bottom-emitting light emitting device in one second light emitting region 3 adjacent to the first light emitting region 2 to emit light. When the one second light emitting region adjacent to the first light emitting region includes a red bottom-emitting light emitting device, the second pixel circuit 26 drives the red bottom-emitting light emitting device to emit light. When the second light emitting region adjacent to the first light emitting region includes a blue bottom-emitting light emitting device, the second pixel circuit 26 drives the blue bottom-emitting light emitting device to emit light. When the second light emitting region adjacent to the first light emitting region includes a green bottom-emitting light emitting device, the second pixel circuit 26 drives the green bottom-emitting light emitting device to emit light.

It should be noted that during specific implementation, the gate drive signal lines include, for example, a scanning signal line and a light emitting control signal line.

During specific implementation, as shown in FIGS. 6-8, the signal lines further include a plurality of data signal lines 46 extending in the first direction Y. The data signal line 46 supplies a data signal to the pixel circuit 8.

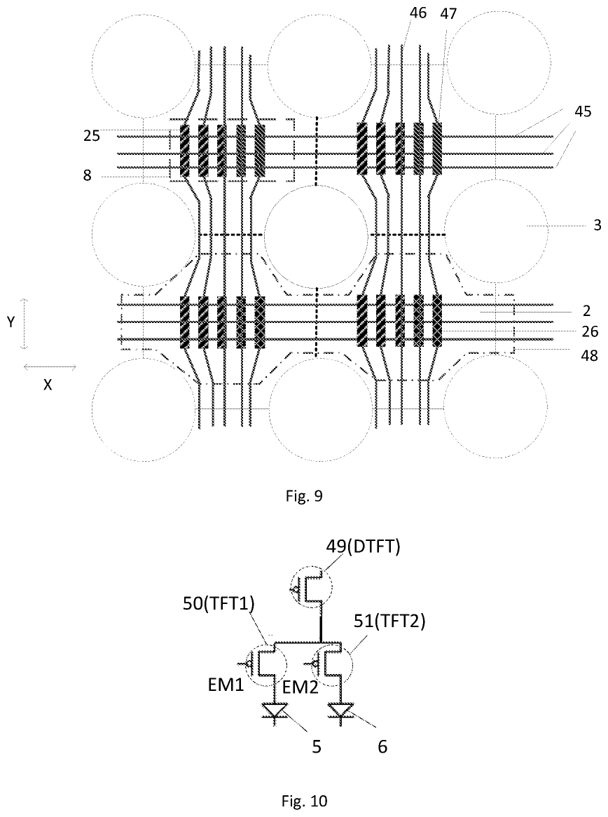

For the display panel as shown in FIG. 5, in some embodiments, as shown in FIG. 9, the plurality of first light emitting regions 2 arranged in an array are divided into a plurality of first light emitting rows 48 extending in the second direction X and arranged in the first direction Y.

One of the pixel circuits 8 corresponding to the first light emitting region 2 includes: three first pixel circuits 25, where each of the first pixel circuits 25 is electrically connected to one of the top-emitting light emitting devices.

One of the pixel circuits 8 corresponding to each of the first light emitting regions 2 in odd-numbered rows of the first light emitting rows 48 further includes: two dummy pixel circuits 47.

One of the pixel circuits 8 corresponding to each of the first light emitting regions 2 in even-numbered rows of the first light emitting rows 48 further includes: two second pixel circuits 26 electrically connected to two of the bottom-emitting light emitting devices adjacent in the second direction X, respectively, where the dummy pixel circuits 47 have the same circuit composition as the second pixel circuits 26.

In some embodiments, as shown in FIG. 9, the plurality of signal lines include: a plurality of gate drive signal lines 45 extending in the second direction X.

In one pixel circuit 8 corresponding to each of the first light emitting regions 2 in the odd-numbered rows of the first light emitting rows 48, the first pixel circuit 25 and the dummy pixel circuit 47 are arranged in the second direction X. In one pixel circuit 8 corresponding to each of the first light emitting regions 2 in the even-numbered rows of the first light emitting rows 48, the first pixel circuit 25 and the second pixel circuit 26 are arranged in the second direction X, and the first pixel circuit 25 and the second pixel circuit 26 share the gate drive signal line 45.

During specific implementation, when the pixel circuit includes two second pixel circuits, the two pixel circuits drive two bottom-emitting light emitting devices in the same column in one pixel group, respectively. In this way, the four second pixel circuits driving one pixel group are located in the same row, and may share the gate drive signal line.

Certainly, alternatively, in some embodiments, each of the pixel circuits in the even-numbered rows of the first light emitting rows may include dummy pixel circuits, and each of the pixel circuits in the odd-numbered rows of the first light emitting rows may include second pixel circuits.

In some embodiments, in the display panel as shown in FIG. 5, the first pixel circuit 25 has the same circuit composition as the second pixel circuit 26.

During specific implementation, the first pixel circuit and the second pixel circuit include thin film transistors and capacitors.

In some embodiments, as shown in FIG. 1, a buffer layer 19 is further arranged between the light shielding layer 17 and the film layer in which the driving circuits are located. The film layer in which the driving circuits are located specifically includes: an active layer, a first gate insulating layer 20, a first gate metal layer, a second gate insulating layer 21, a second gate metal layer, an interlayer insulating layer 22, a source-drain electrode layer, and a planar layer 23. The active layer includes: an active layer 27 of the thin film transistor in the first pixel circuit 25 and an active layer 32 of the thin film transistor in the second pixel circuit 26. The first gate metal layer includes: a gate electrode 28 of the thin film transistor in the first pixel circuit 25 and a gate electrode 33 of the thin film transistor in the second pixel circuit 26. The second gate metal layer includes: a capacitor electrode 29 of the thin film transistor in the first pixel circuit 25 and a capacitor electrode 34 of the thin film transistor in the second pixel circuit 26. A source-drain electrode metal layer includes: a source electrode 30 and a drain electrode 31 of the thin film transistor in the first pixel circuit 25 and a source electrode 35 and a drain electrode 36 of the thin film transistor in the second pixel circuit 26. The first anode 10 is electrically connected to the drain electrode 31 of the thin film transistor in the first pixel circuit 25 through a via hole of the planar layer 23. The second anode 13 is electrically connected to the drain electrode 36 of the thin film transistor in the second pixel circuit 26 through a via hole of the planar layer 23. In FIG. 1, the display panel further includes a pixel defining layer 24.

During specific implementation, the display panel further includes a packaging layer on one side of the third cathode facing away from the second cathode.

Alternatively, when the first light emitting region includes the same quantity of light emitting devices as the second light emitting region, the top-emitting light emitting devices and the bottom-emitting light emitting devices may share some of circuits.

In some embodiments, each of the first light emitting regions includes m of the top-emitting light emitting devices, and each of the second light emitting regions includes m of the bottom-emitting light emitting devices, where m is a positive integer.

As shown in FIG. 1, each of the pixel circuits includes: m third pixel circuits 49; and m fourth pixel circuits, where each of the fourth pixel circuits includes: a first sub-pixel circuit 50 and a second sub-pixel circuit 51 electrically connected to the third pixel circuit 49; the first sub-pixel circuit 50 is further electrically connected to the top-emitting light emitting device 5, and the second sub-pixel circuit 51 is further electrically connected to the bottom-emitting light emitting device 6; and the light emitting devices electrically connected to the first sub-pixel circuit 50 and the second sub-pixel circuit 51 which are electrically connected to the same third pixel circuit 49 have the same light color.

In the display panel provided by the embodiment of the present disclosure, the top-emitting light emitting devices and the bottom-emitting light emitting devices share the third pixel circuit, and the first sub-pixel circuit and the third pixel circuit control the top-emitting light emitting devices to emit light. Compared with a condition that the first pixel circuit and the second pixel circuit control the top-emitting light emitting devices and the bottom-emitting light emitting devices to emit light respectively, by using the second sub-pixel circuit and the third pixel circuit, the quantity of the pixel circuits arranged in the first light emitting region and the quantity of some of the signal lines may be reduced. Further, a wiring space of some of the signal lines can be reduced, a light emitting area of the second light emitting region can be improved, and an aperture ratio of bottom emission pixels can be enhanced.

In some embodiments, as shown in FIG. 10, the third pixel circuit 49 includes: a driver transistor DTFT.

The signal line includes: a first light emitting control signal line EM1 and a second light emitting control signal line EM2.

The first sub-pixel circuit 50 includes: a first transistor TFT1, where a source electrode of the first transistor TFT1 is electrically connected to a drain electrode of the driver transistor DTFT, a gate electrode of the first transistor TFT1 is electrically connected to the first light emitting control signal line EM1, and a drain electrode of the first transistor TFT1 is electrically connected to the top-emitting light emitting device 5.

The second sub-pixel circuit 51 includes: a second transistor TFT2, where a source electrode of the second transistor TFT2 is electrically connected to a drain electrode of the driver transistor DTFT, a gate electrode of the second transistor TFT2 is electrically connected to the second light emitting control signal line EM2, and a drain electrode of the second transistor TFT2 is electrically connected to the bottom-emitting light emitting device 6.

In the display panel provided by the embodiment of the present disclosure, for the driving circuit of a pair of top-emitting light emitting device and bottom-emitting light emitting device, only two transistors and their light emitting control signal lines are added between the third pixel circuit and the light emitting devices, such that the quantity of the driving circuits in the first light emitting region can be greatly reduced, and an occupied area of the driving circuits can be effectively saved. Further, an area of the second light emitting region can be increased, and a bottom emission aperture ratio and pixels per inch (PPI) of back display can be improved.

During specific implementation, only the light emitting devices in the first light emitting region can emit light by controlling the first transistor on and the second transistor off. Alternatively, only the light emitting devices in the second light emitting region can emit light by controlling the first transistor off and the second transistor on. Certainly, alternatively, the light emitting devices in the first light emitting region and the light emitting devices in the second light emitting region can emit light by controlling both the first transistor and the second transistor on.

It should be noted that FIG. 10 only shows a group of third pixel circuit and fourth pixel circuit.

It should be noted that during specific implementation, the first pixel circuit, the second pixel circuit and the third pixel circuit generally need to be further provided with a plurality of transistors and capacitors. The third pixel circuit may have the same composition as the first pixel circuit and the second pixel circuit. In the display panel provided by the embodiment of the present disclosure, compared with a solution of driving the light emitting devices in two different light emitting regions to emit light by using two third pixel circuits, a solution of adding two transistors to drive the light emitting devices in two different light emitting regions to emit light can greatly reduce electrical devices of the pixel circuits and reduce the quantity of the signal lines.

In some embodiments, for the display panel as shown in FIG. 2, only three groups of third pixel circuits and fourth pixel circuits as shown in FIG. 10 need to be arranged in each of the first light emitting regions.

In some embodiments, for the display panel as shown in FIG. 3, only two groups of third pixel circuits and fourth pixel circuits as shown in FIG. 10 need to be arranged in each of the first light emitting regions.

An embodiment of the present disclosure provides a display apparatus. The display apparatus includes the display panel provided by the embodiments of the present disclosure.

The display apparatus provided by the embodiment of the present disclosure is any product or component with a display function, such as a mobile phone, a tablet computer, a television, a display, a notebook computer, a digital photo frame, and a navigator. Other essential components of the display apparatus should be understood by those of ordinary skill in the art, which are not repeated herein and should not limit the present disclosure. Reference may be made to the embodiments of the display panel for implementation of the display apparatus, which will not be repeated herein.

In conclusion, in the display panel and the display apparatus provided by the embodiment of the present disclosure, the top-emitting light emitting devices emitting light from the front surface and the bottom-emitting light emitting devices emitting light from the back surface are simultaneously formed on a transparent substrate, such that the display panel can emit light and display a picture on the front surface and the back surface simultaneously, that is, can achieve double-sided-screen display. Compared with a conventional solution of achieving double-sided-screen display by attaching two screens to each other, the solution of the present disclosure achieves double-sided-screen display by using only one display panel. In this way, the double-sided display panel provided by the embodiment of the present disclosure well achieves a thin and light design, and can reduce cost of a display screen. Moreover, the driving circuits are only arranged in the first light emitting regions, that is, orthographic projections of the driving circuits on the transparent substrate do not overlap with the second light emitting regions, and therefore, a light emitting area of the second light emitting regions can be increased, light emitting efficiency of bottom emission can be improved, and further a display effect of back display of bottom emission can be improved.

Apparently, those skilled in the art can make various modifications and variations to the present disclosure without departing from the spirit and scope of the present disclosure. In this way, if the modifications and variations of the present disclosure fall within the scope of the claims of the present disclosure and their equivalent technologies, the present disclosure is also intended to include the modifications and variations.

1. A display panel, comprising:
a transparent substrate, comprising a display region, wherein the display region comprises a plurality of first light emitting regions arranged in an array in a first direction and a second direction, and a plurality of second light emitting regions arranged in an array in the first direction and the second direction, the first light emitting regions and the second light emitting regions are alternately arranged in a third direction, the first direction intersects with the second direction, and the third direction intersects with both the first direction and the second direction;
light emitting devices on one side of the transparent substrate, comprising top-emitting light emitting devices in the first light emitting regions and bottom-emitting light emitting devices in the second light emitting regions; and
driving circuits in the first light emitting regions and between a film layer in which the light emitting devices are located and the transparent substrate, electrically connected to the light emitting devices, wherein the driving circuits comprise a plurality of pixel circuits of which a quantity is equal to a quantity of the first light emitting regions, and a plurality of signal lines electrically connected to the pixel circuits.

2. The display panel according to claim 1, wherein the top-emitting light emitting device comprises:
a first anode, comprising a reflective material;
a first light emitting layer on one side of the first anode facing away from the driving circuit; and
a first cathode on one side of the first light emitting layer facing away from the first anode, comprising a light transmitting material; and
the bottom-emitting light emitting device comprises:
a second anode, comprising a light transmitting material and located in a same film layer as the first anode;
a second light emitting layer on one side of the second anode facing away from the driving circuit and in the same film layer as the first light emitting layer;
a second cathode, comprising a light transmitting material, located on one side of the second light emitting layer facing away from the second anode, and arranged in the same layer as the first cathode to form an entire surface connected electrode; and
a third cathode in the second light emitting region and on one side of the second cathode facing away from the second light emitting layer, comprising a reflective material.

3. The display panel according to claim 1 or 2, further comprising:
a light shielding layer between the transparent substrate and a film layer in which the driving circuits are located, wherein the plurality of the first light emitting regions are connected to one another, and the light shielding layer covers a zone formed by the plurality of first light emitting regions connected to one another; and the light shielding layer further has first apertures exposing the second light emitting regions, and a quantity of the first apertures is equal to a quantity of the second light emitting regions.

4. The display panel according to claim 1, wherein a quantity of the top-emitting light emitting devices comprised in each of the first light emitting regions is equal to a quantity of the bottom-emitting light emitting devices comprised in each of the second light emitting regions.

5. The display panel according to claim 4, wherein types of light colors of the top-emitting light emitting devices comprised in the first light emitting region are the same as types of light colors of the bottom-emitting light emitting devices comprised in the second light emitting region.

6. The display panel according to claim 5, wherein each of the first light emitting regions comprises: a red top-emitting light emitting device, a blue top-emitting light emitting device, and a green top-emitting light emitting device; and
each of the second light emitting regions comprises: a red bottom-emitting light emitting device, a blue bottom-emitting light emitting device, and a green bottom-emitting light emitting device.

7. The display panel according to claim 4, wherein the first light emitting regions arranged in the array are divided into a plurality of first light emitting columns extending in the first direction and arranged in the second direction; and the plurality of second light emitting regions arranged in the array are divided into a plurality of second light emitting columns extending in the first direction and arranged in the second direction;
in odd-numbered columns of the first light emitting columns, types of light colors of the top-emitting light emitting devices comprised in each of the first light emitting regions are the same; in even-numbered columns of the first light emitting columns, types of light colors of the top-emitting light emitting devices comprised in each of the first light emitting regions are the same; and types of light colors of the top-emitting light emitting devices comprised in each of the first light emitting regions in the odd-numbered columns of the first light emitting columns are not exactly the same as types of light colors of the top-emitting light emitting devices comprised in each of the first light emitting regions in the even-numbered columns of the first light emitting columns;
in odd-numbered columns of the second light emitting columns, types of light colors of the bottom-emitting light emitting devices comprised in each of the second light emitting regions are the same; in even-numbered columns of the second light emitting columns, types of light colors of the bottom-emitting light emitting devices comprised in each of the second light emitting regions are the same; and types of light colors of the bottom-emitting light emitting devices comprised in each of the second light emitting regions in the odd-numbered columns of the second light emitting columns are not exactly the same as types of light colors of the bottom-emitting light emitting devices comprised in each of the second light emitting regions in the even-numbered columns of the second light emitting columns; and
the types of the light colors of the top-emitting light emitting devices comprised in each of the first light emitting regions in the odd-numbered columns of the first light emitting columns are the same as types of the light colors of the bottom-emitting light emitting devices comprised in each of the second light emitting regions in the odd-numbered columns of the second light emitting columns; and the types of the light colors of the top-emitting light emitting devices comprised in each of the first light emitting regions in the even-numbered columns of the first light emitting columns are the same as types of the light colors of the bottom-emitting light emitting devices comprised in each of the second light emitting regions in the even-numbered columns of the second light emitting columns.

8. The display panel according to claim 7, wherein each of the first light emitting regions in the odd-numbered columns of the first light emitting columns comprises: a red top-emitting light emitting device and a green top-emitting light emitting device arranged in the second direction; and each of the first light emitting regions in the even-numbered columns of the first light emitting columns comprises: a blue top-emitting light emitting device and the green top-emitting light emitting device arranged in the second direction; and
each of the second light emitting regions in the odd-numbered columns of the second light emitting columns comprises: a red bottom-emitting light emitting device and a green bottom-emitting light emitting device arranged in the second direction; and each of the second light emitting regions in the even-numbered columns of the second light emitting columns comprises: a blue bottom-emitting light emitting device and the green bottom-emitting light emitting device arranged in the second direction.

9. The display panel according to claim 1, wherein a quantity of the top-emitting light emitting devices comprised in each of the first light emitting regions is different from a quantity of the bottom-emitting light emitting devices comprised in each of the second light emitting regions.

10. The display panel according to claim 9, wherein each of the first light emitting regions comprises three top-emitting light emitting devices having different light colors; and
each of the second light emitting regions comprises one bottom-emitting light emitting device.

11. The display panel according to claim 10, wherein each of the first light emitting regions comprises: a red top-emitting light emitting device, a blue top-emitting light emitting device, and a green top-emitting light emitting device; and
the plurality of second light emitting regions arranged in the array are divided into a plurality of second light emitting groups arranged in the second direction, wherein
each of the second light emitting groups comprises: a second red light emitting column, a second blue light emitting column and a second green light emitting column extending in the first direction and sequentially arranged in the second direction;
each of the second light emitting regions in the second red light emitting column comprises: a red bottom-emitting light emitting device;
each of the second light emitting regions in the second blue light emitting column comprises: a blue bottom-emitting light emitting device; and
each of the second light emitting regions in the second green light emitting column comprises: a green bottom-emitting light emitting device.

12. The display panel according to claim 10, wherein each of the first light emitting regions comprises: a red top-emitting light emitting device, a blue top-emitting light emitting device, and a green top-emitting light emitting device; and
the plurality of second light emitting regions arranged in the array are divided into a plurality of pixel groups, and each of the pixel groups comprises four of the second light emitting regions in two rows and two columns, wherein
each of the pixel groups at least comprises a red bottom-emitting light emitting device, a blue bottom-emitting light emitting device, and a green top-emitting light emitting device.

13. The display panel according to claim 4,
wherein each of the first light emitting regions comprises m of the top-emitting light emitting devices, and each of the second light emitting regions comprises n of the bottom-emitting light emitting devices, wherein m and n are both positive integers; and
one of the pixel circuits corresponding to the first light emitting region comprises:
m first pixel circuits, wherein each of the first pixel circuits is electrically connected to one of the top-emitting light emitting devices; and
n second pixel circuits, wherein each of the second pixel circuits is electrically connected to one of the bottom-emitting light emitting devices.

14. The display panel according to claim 13, wherein the plurality of signal lines comprise:
a plurality of gate drive signal lines extending in the second direction, wherein
the first pixel circuit and the second pixel circuit in one same pixel circuit are arranged in the second direction, and the first pixel circuit and the second pixel circuit in the same pixel circuit share the gate drive signal line.

15. The display panel according to claim 12, wherein the plurality of first light emitting regions arranged in an array are divided into a plurality of first light emitting rows extending in the second direction and arranged in the first direction;
one of the pixel circuits corresponding to the first light emitting region comprises:
three first pixel circuits, wherein each of the first pixel circuits is electrically connected to one of the top-emitting light emitting devices;
one of the pixel circuits corresponding to each of the first light emitting regions in odd-numbered rows of the first light emitting rows further comprises:
two dummy pixel circuits; and
one of the pixel circuits corresponding to each of the first light emitting regions in even-numbered rows of the first light emitting rows further comprises:
two second pixel circuits electrically connected to two of the bottom-emitting light emitting devices adjacent in the second direction, respectively, wherein the dummy pixel circuits have the same circuit composition as the second pixel circuits.

16. The display panel according to claim 15, wherein the plurality of signal lines comprise:
a plurality of gate drive signal lines extending in the second direction, wherein
in one of the pixel circuits corresponding to each of the first light emitting regions in the odd-numbered rows of the first light emitting rows, the first pixel circuit and the dummy pixel circuit are arranged in the second direction; and in one of the pixel circuits corresponding to each of the first light emitting regions in the even-numbered rows of the first light emitting rows, the first pixel circuit and the second pixel circuit are arranged in the second direction, and the first pixel circuit and the second pixel circuit share the gate drive signal line.

17. The display panel according to claim 13, wherein the first pixel circuit has the same circuit composition as the second pixel circuit.

18. The display panel according to claim 4, wherein each of the first light emitting regions comprises m of the top-emitting light emitting devices, and each of the second light emitting regions comprises m of the bottom-emitting light emitting devices, wherein m is a positive integer; and
each of the pixel circuits comprises:
m third pixel circuits; and
m fourth pixel circuits, wherein each of the fourth pixel circuits comprises: a first sub-pixel circuit and a second sub-pixel circuit that are electrically connected to the third pixel circuit; the first sub-pixel circuit is further electrically connected to the top-emitting light emitting device, and the second sub-pixel circuit is further electrically connected to the bottom-emitting light emitting device; and light emitting devices electrically connected to the first sub-pixel circuit and the second sub-pixel circuit which are electrically connected to one same third pixel circuit have the same light color.

19. The display panel according to claim 18, wherein the third pixel circuit comprises: a driver transistor;
the signal line comprises: a first light emitting control signal line and a second light emitting control signal line;
the first sub-pixel circuit comprises: a first transistor, wherein a source electrode of the first transistor is electrically connected to a drain electrode of the driver transistor, a gate electrode of the first transistor is electrically connected to the first light emitting control signal line, and a drain electrode of the first transistor is electrically connected to the top-emitting light emitting device; and
the second sub-pixel circuit comprises: a second transistor, wherein a source electrode of the second transistor is electrically connected to a drain electrode of the driver transistor, a gate electrode of the second transistor is electrically connected to the second light emitting control signal line, and a drain electrode of the second transistor is electrically connected to the bottom-emitting light emitting device.

20. A display apparatus, comprising the display panel according to claim 1.
